(19) United States
(12) Patent Application Publication
(10) Pub. No.: US 2017/0310312 A1
(43) Pub. Date: Oct. 26, 2017

(54) CLOCK SPINE WITH TAP POINTS

(71) Applicant: QUALCOMM Incorporated, San Diego, CA (US)

(72) Inventors: Rajesh ARIMILLI, Bangalore (IN); Apurv NARKHEDE, Vapi (IN); Ajay NAWANDHAR, Bangalore (IN)

(21) Appl. No.: 15/134,994

(22) Filed: Apr. 21, 2016

(51) Int. Cl. H03K 5/15

(52) U.S. Cl. CPC H03K 5/15026

(57) ABSTRACT

Apparatuses and methods to relay a clock signal to clock loads are presented. An apparatus includes a clock spine to conduct a clocking signal. The clock spine includes multiple taps points distributed unevenly on the clock spine. The apparatus further includes multiple clock buffers. Each of the multiple clock buffers is connected to a corresponding one of the multiple tap points. The method includes conducting a clocking signal on a clock spine having multiple taps points. The multiple tap points are distributed unevenly on the clock spine. The method further includes buffering the clocking signal at each of the multiple tap points. Another method includes forming a clock spine to conduct a clocking signal. The clock spine includes multiple taps points. The multiple tap points are distributed unevenly on the clock spine. The method further includes forming multiple clock buffers.

### BACKGROUND

### Field

The present disclosure relates generally to electronic circuits, and more particularly, to an integrated circuit (IC) with a clock spine and tap points on the clock spine.

### Background

Integrated circuits (ICs) are increasingly important for modern life. For example, wireless communication technologies and devices (e.g., cellular phones, tablets, laptops, etc.) have grown in popularity and usage over the past decade. These electronic apparatuses have grown in complexity and now commonly incorporate multiple processors (e.g., baseband processor and/or application processor) and other ICs that allow the users to run complex and power intensive software applications (e.g., music players, web browsers, video streaming applications, etc.). To meet the increasing performance demand, these ICs have increased in complexity and operate at clock frequencies in the gigahertz range.

Consequently, providing clocking signals in such ICs is an increasing concern. For example, clocking signal variation (known as clock skew) within an IC may limit operating frequencies of the IC due to the clock skew. Thus, one design concern is how to limit clock skew in ICs.

### SUMMARY

Aspects of an apparatus are disclosed. In one implementation, the apparatus includes a clock spine to conduct a clocking signal. The clock spine includes a plurality of taps points distributed unevenly on the clock spine. The apparatus further includes a plurality of clock buffers. Each of the plurality of clock buffers is connected to a corresponding one of the plurality of tap points.

Aspects of a method for operating an integrated circuit are disclosed. The method includes conducting a clocking signal on a clock spine having a plurality of taps points. The plurality of tap points is distributed unevenly on the clock spine. The method further includes buffering the clocking signal at each of the plurality of tap points.

Further aspects of an apparatus are disclosed. The apparatus includes means for conducting a clocking signal. The means for conducting includes a plurality of taps points distributed unevenly on the means for conducting. The apparatus further includes means for buffering the clocking signal at the plurality of tap points.

Further aspects of a method for manufacturing an integrated circuit are disclosed. The method includes forming a clock spine to conduct a clocking signal. The clock spine includes a plurality of taps points distributed unevenly on the clock spine. The method further includes forming a plurality of clock buffers, each of the plurality of clock buffers being connected to a corresponding one of the plurality of tap points.

It is understood that other aspects of apparatus and methods will become readily apparent to those skilled in the art from the following detailed description, wherein various aspects of apparatus and methods are shown and described by way of illustration. As will be realized, these aspects may be implemented in other and different forms and its several details are capable of modification in various other respects. Accordingly, the drawings and detailed description are to be regarded as illustrative in nature and not as restrictive.

### BRIEF DESCRIPTION OF THE DRAWINGS

Various aspects of apparatus and methods will now be presented in the detailed description by way of example, and not by way of limitation, with reference to the accompanying drawings, wherein:

FIG. 1 is a diagram of an IC with clock spines.

FIG. 2 is a block diagram of an exemplary embodiment of tap points on a clock spine.

FIG. 3 is a block diagram of clock loads arranged in clusters with each cluster having a corresponding center generated by an aspect that reduces clock skew of a clock signal distributed.

FIG. 4 is a flowchart of an exemplary embodiment of a k-means clustering process.

FIG. 5 is a flowchart of an aspect for selecting an initial set of centroids.

FIG. 6A is a block diagram of a tap point and a center of a cluster in an aspect.

FIG. 6B is a block diagram of an exemplary embodiment of a tap point and multiple centers of clusters.

FIG. 7 is a flowchart for operating the clock spine and the clock buffers connected to the tap points on the clock spine.

FIG. 8 is a flowchart of a method for manufacturing the IC of FIG. 1.

### DETAILED DESCRIPTION

The detailed description set forth below in connection with the appended drawings is intended as a description of various exemplary embodiments of the present invention and is not intended to represent the only embodiments in which the present invention may be practiced. The detailed description includes specific details for the purpose of providing a thorough understanding of the present invention. However, it will be apparent to those skilled in the art that the present invention may be practiced without these specific details. In some instances, well-known structures and components are shown in block diagram form in order to avoid obscuring the concepts of the present invention. Acronyms and other descriptive terminology may be used merely for convenience and clarity and are not intended to limit the scope of the invention.

Various apparatuses and methods for providing clocking signals are presented throughout this disclosure may be incorporated within various apparatuses. By way of example, various aspects of the disclosed apparatuses and methods herein may be implemented as or in a stand-alone IC. Such aspects may also be included in any system, or any portion of the system (e.g., modules, components, circuits, or the like incorporating the IC or part of the IC), or any intermediate product where the IC or system is combined with other ICs or systems (e.g., a video card, a motherboard, etc.) or any end product (e.g., mobile phone, personal digital assistant (PDA), desktop computer, laptop computer, palm-sized computer, tablet computer, work station, game console, media player, computer based simulators, wireless communication attachments for laptops, or the like).

The word “exemplary” is used herein to mean serving as an example, instance, or illustration. Any embodiment described herein as “exemplary” is not necessarily to be construed as preferred or advantageous over other embodiments. Likewise, the term “embodiment” of an apparatus or method does not require that all embodiments of the invention include the described components, structure, features, functionality, processes, advantages, benefits, or modes of operation.

The terms “connected,” “coupled,” or any variant thereof, mean any connection or coupling, either direct or indirect, between two or more elements, and can encompass the presence of one or more intermediate elements between two elements that are “connected” or “coupled” together. The coupling or connection between the elements can be physical, logical, or a combination thereof. As used herein, two elements can be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Any reference to an element herein using a designation such as “first,” “second,” and so forth does not generally limit the quantity or order of those elements. Rather, these designations are used herein as a convenient method of distinguishing between two or more elements or instances of an element. Thus, a reference to first and second elements does not mean that only two elements can be employed, or that the first element must precede the second element.

As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of the stated features, integers, steps, operations, elements, and/or components, but do not preclude the presence or addition of one or more other features, integers, steps, operations, elements, components, and/or groups thereof.

Various aspects of apparatuses and methods to provide clock signals will now be presented. However, as those skilled in the art will readily appreciate, such aspects may be extended beyond the configurations presented herein. Accordingly, all exemplary embodiments presented are intended only to illustrate exemplary aspects of the apparatuses and methods to provide clock signals with the understanding that such aspects may be extended to a wide range of applications.

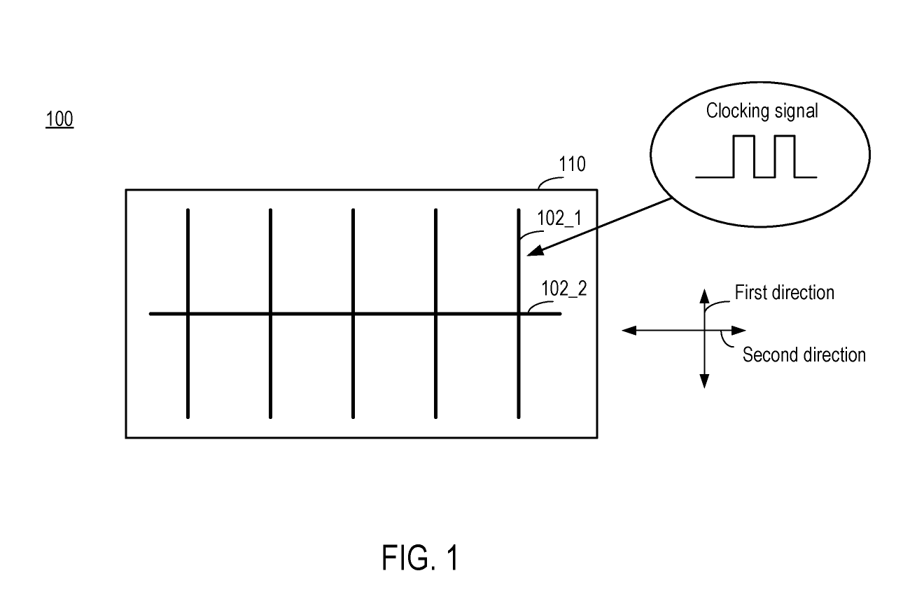

FIG. 1 is a diagram of an IC with clock spines. The block diagram 100 includes an IC 110. The IC 110 includes clock spines 102_1 extending in a first direction (e.g., a vertical direction) and a clock spine 102_2 extending in a second direction (e.g., the horizontal direction). The first and second directions may be orthogonal. The clock spines (e.g., clock spines 102_1 and 102_2, or collectively 102) may be communicatively (e.g., electrically) coupled conductors to conduct (e.g., to propagate) a clocking signal.

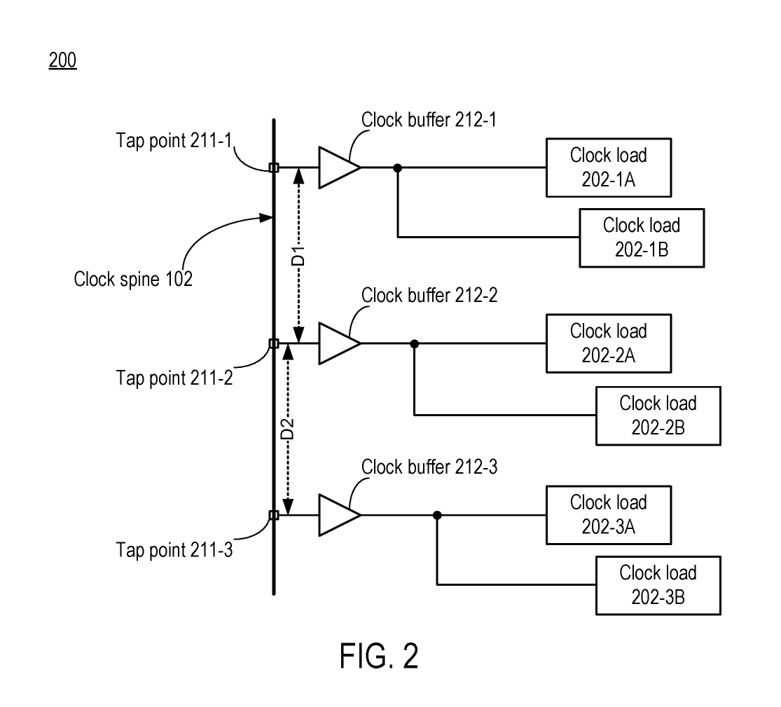

FIG. 2 is a block diagram of an exemplary embodiment of tap points on a clock spine. The block diagram 200 includes the clock spine 102 to conduct a clock signal to various clocks loads (e.g., clock loads 202-1, 202-2, and 202-3 or collectively 202). A clock load 202 may be, for example, one or more circuits on the IC 110 clocked by the clock signal conducted on the clock spine 102. The clock spine 102 includes tap points 211-1, 211-2, and 211-3 (collectively 211). A clock buffer (e.g., the clock buffers 212-1, 212-2, and 212-3, or collectively 212) is electrically connected to a corresponding one of the tap points 211-1, 211-2, and 211-3.

The clock buffer relays the clock signal conducted by the clock spine 102 to the corresponding clock loads (e.g., clock loads 202-1, 202-2, and 202-3). For example, the clock buffer 212-1 is electrically connected to the tap point 211-1, and relays the clocking signal conducted on the clock spine 102 to the clock loads 202-1A and 202-1B. In such fashion, the clock signal conducted by the clock spine 102 is provided to the clock loads on the IC 110.

In some examples, the tap points 211-1, 211-2, and 211-3 are evenly distributed on the clock spine 102. For example, the distance D1 between the tap points 211-1 and 211-2 and the distance D2 between the tap points 211-2 and 211-3 are the same. For example, a clock spine 102 may be divided evenly to place the tap points 211. Iterations of simulations may be performed to find the optimal distance among the tap points 211 (e.g., distances D1 and D2). However, in these examples, the locations of the tap points 211 may not be determined based on the clock loads 202. Thus, the optimal distance of the evenly distributed tap points 211 may not be the optimal placements of the tap points 211 in terms of minimizing clock skew at the various clock loads 202. That is, the evenly distributed tap points 211 may not produce the minimum clock skew when providing the clocking signal (conducted by the clock spine 102). Thus, one design challenge is to improve upon this scheme of providing clocking signal to the clock loads 202.

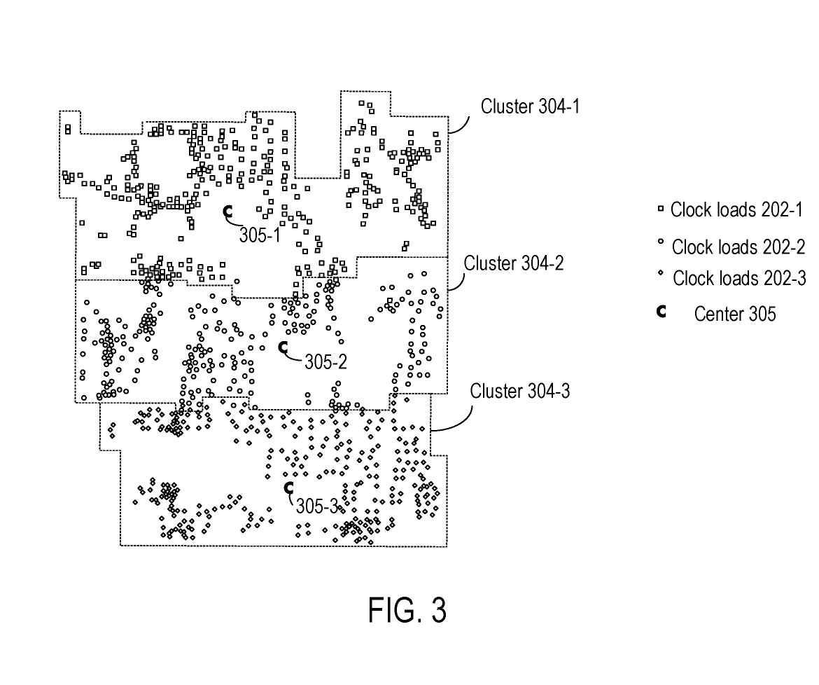

In some aspects, the tap points 211 may be unevenly distributed on the clock spine 102. For example, the distances D1 and D2 are not equal, and the placement of one of the tap points 211 is not directly based the placement of another one of the tap points 211. In some aspects, the placement of the tap points 211 may be based on the clock loads 202 arranged in clusters as further illustrated by FIG. 3 and corresponding text below.

FIG. 3 is a block diagram of clock loads arranged in clusters with each cluster having a corresponding center generated by an aspect that reduces clock skew of a clock signal distributed. The block diagram 300 includes the clock loads 202 arranged as clusters 304-1, 304-2, and 304-3 (collectively 304). Each of the clusters 304 may include a center 305 (e.g., centers 305-1, 305-2, and 305-3). A center 305 may be, for example, a geographical center. In some examples, the center 305 may be a geometrical center or a centroid. Further details regarding determining the center 305 of a cluster 304 are presented below. In some aspects, the arrangement of the clusters 304 is based on the locations of the clock loads 202. For example, the clusters 304 may be determined by k-means clustering. The goal of k-means clustering algorithms is to minimize the sum of distances D(x) (e.g., the sum of squares of distances or D(x)²) from each clock load 202 to the center 305 of the cluster 304 to which the clock load 202 belongs. In other words, a center 305 may be determined based on squares of distances (e.g., D(x)²) from the center 305 to the clock loads 202 of the cluster 304.

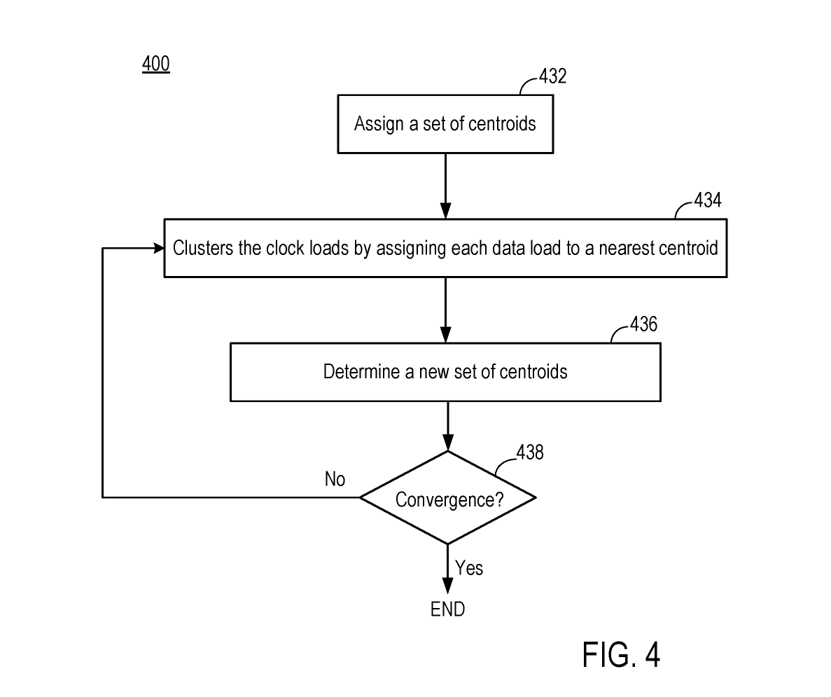

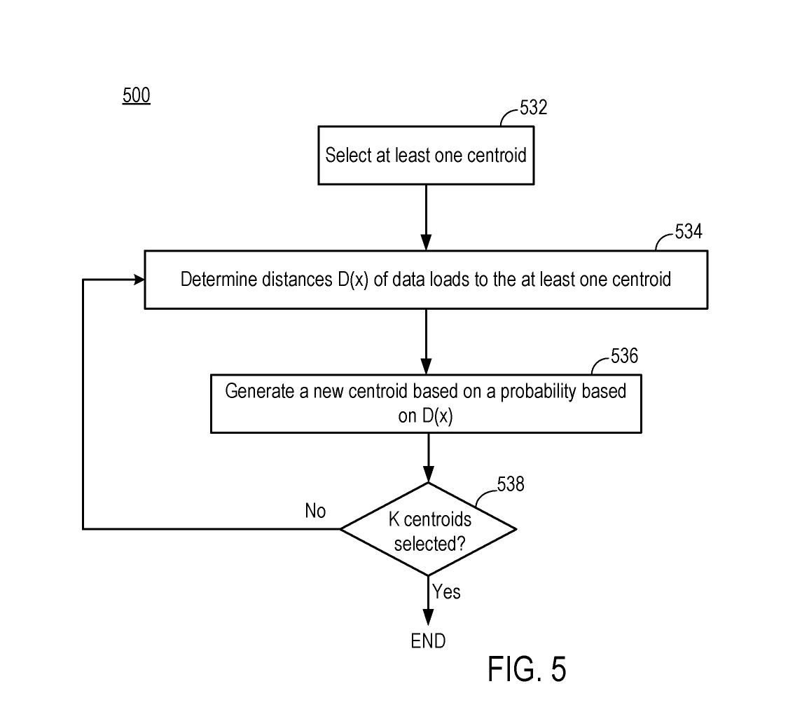

FIG. 4 is a flowchart of an exemplary embodiment of a k-means clustering process. The flowchart 400 illustrates a relationship of the clusters (e.g., clusters 304) and data loads (e.g., clock loads 202). Another aspect of the flowchart 400 provides a process or method to manufacture the IC 110 with the clock spines 102 and the clock loads 202. At 432, a set of centroids (e.g., centers 305) are assigned. Such assignment may be, for example, random. An example of an assignment algorithm is provided with FIG. 5. At 434, the clock loads 202 are clustered by assigning each clock load 202 to a nearest centroid or center (e.g., based on D(x)). At 436, a new set of centroids (e.g., centers 305) for each of the clusters of 434 is determined using existing techniques to determine a geometrical center as known in the art. For example, one algorithm provides that a coordinate of a centroid may be the sum of the corresponding coordinates of the clock loads 202 divided by the number of the clock loads 202.

At 438, whether a convergence has been achieved is determined. For example, if no changes or minimum changes (which may be predetermined or set by the user) to the centroids resulted from 436, a convergence is achieved, and the process ends. If a convergence has not been achieve, the flow goes to 434 for further iterations.

FIG. 5 is a flowchart of an aspect for selecting an initial set of centroids. The flowchart 500 may provide an example of operations performed by block 432 of the flowchart 400. At 532, at least one centroid (or center) is assigned randomly. At 534, distances D(x) of clock loads 202 to the at least one centroid are determined. In some examples, for more than one centroid, the distances of the clock loads 202 to the nearest centroid are determined.

At 536, a new centroid is generated based on a probability based on D(x). Thus, a location that is further away from the initial centroid of 532 is more likely to be selected to be a new centroid. At 538, whether K centroids have been selected is determined. The number of centroids K may be a predetermined target. If K centroids have been selected, the process ends. If less than K centroids have been selected, the process goes to 534 to select more new centroids.

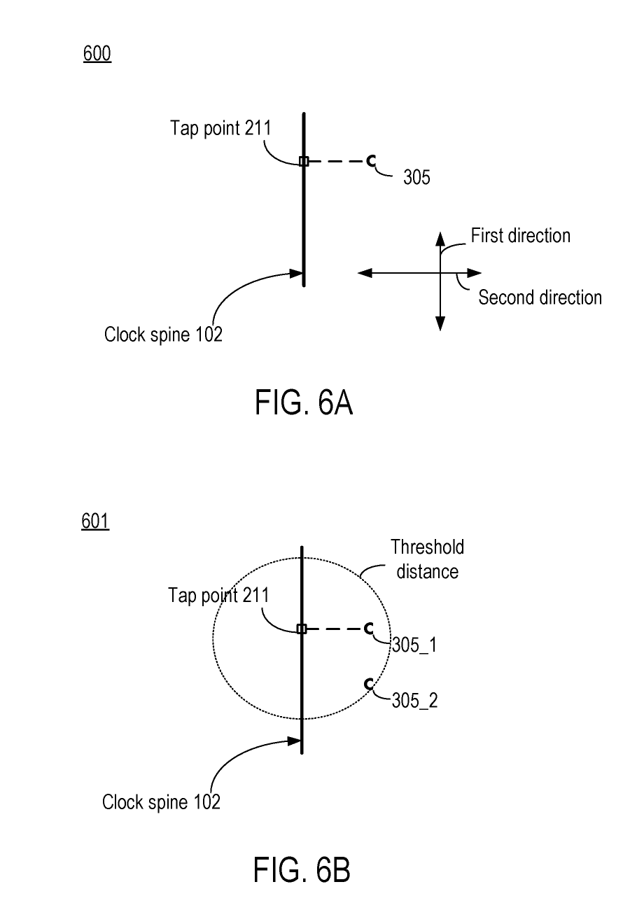

FIG. 6A is a block diagram of a tap point and a center of a cluster in an aspect. The block diagram 600 includes the clock spine 102 extending in a first direction, a tap point 211, and a center of a cluster 304. The tap point 211 is at a nearest point on the clock spine 102 to the center 305. In some examples, the tap point 211 is aligned in a second direction with the center of a cluster 304. In some examples, the first and second directions may be orthogonal. In such fashion, referring to FIGS. 2 and 3, each of the tap points 211-1, 211-2, and 211-3 corresponds to (e.g., being nearest to) a corresponding one of the centers 305-1, 305-2, and 305-3.

FIG. 6B is a block diagram of an exemplary embodiment of a tap point and multiple centers of clusters. The block diagram 601 includes the clock spine 102, a tap point 211, a center 305-1 of the cluster 304-1, and a center 305-2 of the cluster 304-2. In some examples, the tap point 211 may correspond to centers of multiple clusters. For example, the clock buffer 212 may connect to the tap point 211 to relay the clocking signal conducted on the clock spine 102 to two or more clusters 304. For example, the tap point 211 may be within a threshold distance of the center 305-1 of the cluster 304-1 and the center 305-2 of the cluster 304-2. In some examples, such threshold distance may be predetermined or selected by the user. In other words, the tap points that would be serving multiple clusters 304, and the multiple centers 305 of the multiple clusters 304 may be merged into a single tap point 211.

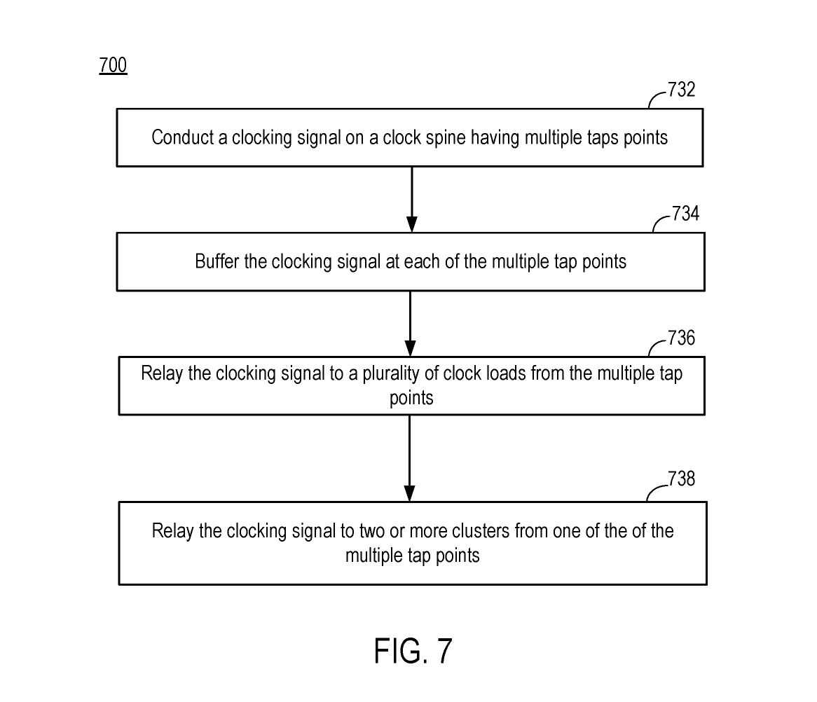

FIG. 7 is a flowchart for operating the clock spine and the clock buffers connected to the tap points on the clock spine. The operations of flowchart 700 may be performed by structures of FIGS. 1, 2, 3, 6A, and 6B. At 732, a clocking signal is conducted on a clock spine having multiple taps points. In some aspects, the clock spine 102 provides the means for conducting a clocking signal. Referring to FIGS. 1 and 2, a clocking signal may be conducted on the clock spine 102. The clock spine 102 may include tap points 211-1, 211-2, and 211-3. In some aspects, the multiple tap points 211 are distributed unevenly on the clock spine 102. For example, the distances D1 (between the tap points 211-1 and 211-2) and D2 (between the tap points 211-2 and 211-3) are not the same in such aspects.

At 734, the clocking signal is buffered at each of the multiple tap points. In some examples, the clock buffer 212 provides the means for buffering the clocking signal. Referring to FIG. 2, a clock buffer 212 is electrically connected at each of the tap points 211-1, 211-2, and 211-3 to buffer the clock signal conducted on the clock spine 102. At 736, the clocking signal is relayed to multiple clock loads from the multiple tap points. Referring to FIG. 2, the clock buffers 212 electrically coupled to the tap point 211 relay the clocking signal to clock loads 202. In some examples, the clock loads 202 may be arranged as multiple clusters 304. Referring to FIG. 3, the clock loads 202 are arranged as clusters 304-1, 304-2, and 304-3.

Each of the clusters 304-1, 304-2, and 304-3 has a center 305. In one aspect, the center 305 may be a geographical center of the cluster 304. In another aspect, the center 305 may be a geometrical center or centroid of the cluster 304. In yet another aspect, the relationship of the center 305 to the clock loads 202 of the cluster 304 may be determined based on squares of distances (D(x)²) from the center 305 to the clock loads 202. The tap point 211 may be a nearest point on the clock spine 102 to the center 305. For example, referring to FIG. 6A, the clock spine 102 may extend in a first direction (e.g., the vertical direction), and the tap point 211 may align in a second direction (e.g., the horizontal direction) with the center 305.

At 738, the clocking signal may be relayed to two or more clusters from one of the multiple tap points. In some example, the one tap point 211 is within a threshold distance of the centers 305 of the two or more clusters 304. Referring to FIG. 6B, both the centers 305-1 (of the cluster 304-1) and 305-2 (of the cluster 304-2) are within the threshold distance of the tap point 211. The clock buffer 212 (not shown for clarity) electrically connected to the tap point 211 relays the clocking signal conducted on the clock spine 102 to the clusters 304-1 and 304-2.

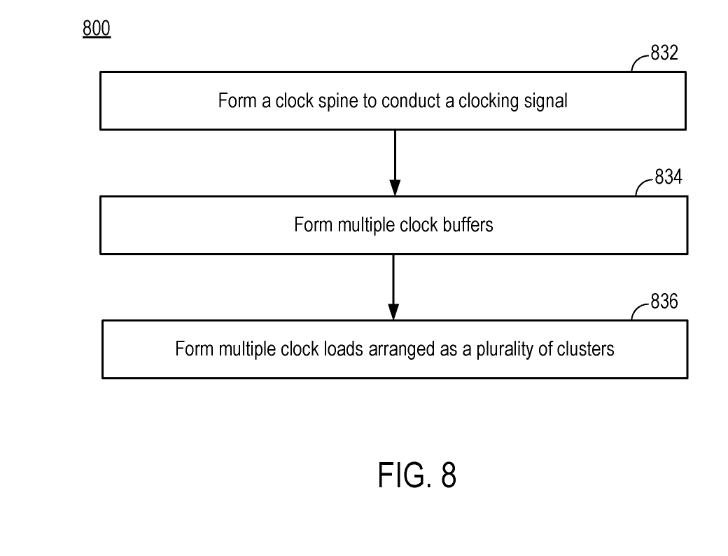

FIG. 8 is a flowchart of a method for manufacturing the IC of FIG. 1. The IC 110 of FIG. 1 may incorporate the structures of FIGS. 2, 3, 6A, and 6B. In some example, the operations may be performed by a semiconductor fab or semiconductor manufacturing equipment using steps such as mask imaging, deposition, diffusion, and etching. These steps may be part of a known semiconductor technology, such as the FinFET transistor technology. Moreover, the operations may be performed in the process of generating the layout of the IC 110. For example, a processor may execute instructions stored in a non-transitory computer media to perform the operations to generate the layout of the IC 110, which is part of the manufacturing process. The operations of flowchart 800 are presented using the layout generation by way of illustration and not limitation.

At 832, a clock spine is formed to conduct a clocking signal. Referring to FIGS. 1 and 2, a clocking signal may be conducted on the clock spine 102. The clock spine 102 may include tap points 211-1, 211-2, and 211-3. In some examples, the multiple tap points 211 are distributed unevenly on the clock spine 102. For example, the distances D1 (between the tap points 211-1 and 211-2) and D2 (between the tap points 211-2 and 211-3) are not the same.

At 834, multiple clock buffers are formed. In some examples, each of the multiple clock buffers 212 is electrically connected to a corresponding one of the multiple tap points 211. Referring to FIG. 2, a clock buffer 212 is electrically connected at each of the tap points 211-1, 211-2, and 211-3 to buffer the clock signal conducted on the clock spine 102. At 836, multiple clock loads arranged as multiple clusters are formed. Referring to FIG. 2, the clock buffers 212 electrically connected to the tap point 211 relays the clocking signal to clock loads 202. In some examples, the clock loads 202 may be arranged as multiple clusters. Referring to FIG. 3, the clock loads 202 are arranged as clusters 304-1, 304-2, and 304-3.

For each of the clusters 304-1, 304-2, and 304-3 a center 305 may be determined/assigned. In one aspect, the center 305 may be a geographical center of the cluster 304. In another aspect, the center 305 may be a geometrical center or centroid of the cluster 304. In yet another aspect, the relationship of the center 305 to the clock loads 202 of the cluster 304 may be determined based on squares of distances (D(x)²) from the center 305 to the clock loads 202. The tap point 211 may be a nearest point on the clock spine 102 to the center 305. For example, referring to FIG. 6A, the clock spine 102 may extend in a first direction (e.g., the vertical direction), and the tap point 211 may align in a second direction (e.g., the horizontal direction) with the center 305.

The specific order or hierarchy of blocks in the method of operation described above is provided merely as an example. Based upon design preferences, the specific order or hierarchy of blocks in the method of operation may be re-arranged, amended, and/or modified. The accompanying method claims include various limitations related to a method of operation, but the recited limitations are not meant to be limited in any way by the specific order or hierarchy unless expressly stated in the claims.

The various aspects of this disclosure are provided to enable one of ordinary skill in the art to practice the present invention. Various modifications to exemplary embodiments presented throughout this disclosure will be readily apparent to those skilled in the art, and the concepts disclosed herein may be extended to other magnetic storage devices. Thus, the claims are not intended to be limited to the various aspects of this disclosure, but are to be accorded the full scope consistent with the language of the claims. All structural and functional equivalents to the various components of the exemplary embodiments described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. §112(f) unless the element is expressly recited using the phrase “means for” or, in the case of a method claim, the element is recited using the phrase “step for.”

1. An apparatus, comprising:
a clock spine configured to conduct a clocking signal, the clock spine having a plurality of taps points, wherein the plurality of tap points are distributed unevenly on the clock spine based on clock loads;
a plurality of clock buffers, each of the plurality of clock buffers being connected to a corresponding one of the plurality of tap points; and
a plurality of clock loads arranged as a plurality of clusters, wherein the plurality of clock buffers relay the clocking signal to the plurality of clock loads, and one of the plurality of tap points is a nearest point on the clock spine to a center of one of the plurality of clusters.

2-3. (canceled)

4. The apparatus of claim 1, wherein the center of the one of the plurality of clusters corresponds to a centroid of the one of the plurality of clusters.

5. The apparatus of claim 1, wherein the center of the one of the plurality of clusters is determined based on squares of distances from the center to the plurality of clock loads of the one of the plurality of clusters.

6. The apparatus of claim 1, wherein the clock spine extends in a first direction, and the one of the plurality of tap points is aligned in a second direction with the center of the one of the plurality of clusters.

7. The apparatus of claim 1, wherein one of the plurality of clock buffers connects to one of the plurality of tap points and relays the clocking signal to two or more of the plurality of clusters, wherein the one of the plurality of tap points is within a threshold distance of a center of each of the two or more of the plurality of clusters.

8. A method for operating an integrated circuit, comprising:
conducting a clocking signal on a clock spine having a plurality of taps points, wherein the plurality of tap points are distributed unevenly on the clock spine based on clock loads;
buffering the clocking signal at each of the plurality of tap points; and
relaying the clocking signal to a plurality of clock loads from the plurality of tap points, wherein the plurality of clock loads is arranged as a plurality of clusters, and wherein one of the plurality of tap points is a nearest point on the clock spine to a center of one of the plurality of clusters.

9-10. (canceled)

11. The method of claim 8, wherein the center of one of the plurality of clusters corresponds to a centroid of the one of the plurality of clusters.

12. The method of claim 8, wherein the center of one of the plurality of clusters is determined based on squares of distances from the center to the plurality of clock loads of the one of the plurality of clusters.

13. The method of claim 8, wherein the clock spine extends in a first direction, and the one of the plurality of tap points is aligned in a second direction with the center of one of the plurality of clusters.

14. The method of claim 8, further comprising:
relaying the clocking signal to two or more of the plurality of clusters from one of the of the plurality of tap points, wherein the one of the plurality of tap points is within a threshold distance of a center of each of the two or more of the plurality of clusters.

15. An apparatus, comprising:
means for conducting a clocking signal, the means for conducting having a plurality of taps points, wherein the plurality of tap points are distributed unevenly on the means for conducting based on clock loads;
means for buffering the clocking signal at the plurality of tap points; and
a plurality of clock loads arranged as a plurality of clusters, wherein the means for buffering relays the clocking signal to the plurality of clock loads and one of the plurality of tap points is a nearest point on the means for conducting to a center of one of the plurality of clusters.

16-17. (canceled)

18. The apparatus of claim 8, wherein the center of one of the plurality of clusters corresponds to a centroid of the one of the plurality of clusters.

19. The apparatus of claim 8, wherein the center of one of the plurality of clusters is determined based on squares of distances from the center to the plurality of clock loads of the one of the plurality of clusters.

20. The apparatus of claim 8, wherein the means for conducting extends in a first direction, and the one of the plurality of tap points is aligned in a second direction with the center of one of the plurality of clusters.

21. The apparatus of claim 8, wherein one of the means for buffering connects to one of the plurality of tap points and relays the clocking signal to two or more of the plurality of clusters, wherein the one of the plurality of tap points is within a threshold distance of a center of each of the two or more of the plurality of clusters.

22. A method for manufacturing an integrated circuit, comprising:
forming a clock spine to conduct a clocking signal, the clock spine having a plurality of taps points, wherein the plurality of tap points are distributed unevenly on the clock spine based on clock loads;
forming a plurality of clock buffers, each of the plurality of clock buffers being connected to a corresponding one of the plurality of tap points; and
forming a plurality of clock loads arranged as a plurality of clusters, wherein the plurality of clock buffers relays the clocking signal to the plurality of clock loads, and one of the plurality of tap points is a nearest point on the clock spine to a center of one of the plurality of clusters.

23-24. (canceled)

25. The method of claim 22, wherein the center of one of the plurality of clusters corresponds to a centroid of the one of the plurality of clusters.

26. The method of claim 22, wherein the center of one of the plurality of clusters is determined based on squares of distances from the center to the clock loads of the one of the plurality of clusters.

27. The method of claim 22, wherein the clock spine extends in a first direction, and the one of the plurality of tap points is aligned in a second direction with the center of one of the plurality of clusters.

28. The method of claim 22, wherein one of the plurality of clock buffers connects to one of the plurality of tap points and relays the clocking signal to two or more of the plurality of clusters, wherein the one of the plurality of tap points is within a threshold distance of a center of each of the two or more of the plurality of clusters.
